(19) United States
(12) Patent Application Publication
(10) Pub. No.: US 2012/0202315 A1
(43) Pub. Date: Aug. 9, 2012

(54) IN-SITU HYDROGEN PLASMA TREATMENT OF AMORPHOUS SILICON INTRINSIC LAYERS

(75) Inventors: HARRY SMITH WHITESELL, III, Santa Clara, CA (US); Gregory Robert Alcott, Liphook (GB)

(73) Assignee: APPLIED MATERIALS, INC., Santa Clara, CA (US)

(21) Appl. No.: 13/360,365

(22) Filed: Jan. 27, 2012

Related U.S. Application Data
(60) Provisional application No. 61/439,190, filed on Feb. 3, 2011.

(51) Int. Cl. H01L 31/0264

(52) U.S. Cl. 438/87; 257/E31.004

(57) ABSTRACT

Embodiments of the invention generally provide methods for forming amorphous silicon-based photovoltaic devices, such as solar cells, by utilizing deposition and plasma treatment steps during a plasma-enhanced chemical vapor deposition (PE-CVD) process. In one embodiments, the method includes exposing a transparent conductive oxide (TCO) layer disposed on a substrate to hydrogen plasma during pretreatment, forming a p-type α-Si film on the TCO layer, forming an α-Si intrinsic film on the p-type α-Si film during a PE-CVD process, and forming an n-type α-Si film on the α-Si intrinsic film. In some examples, the PE-CVD process includes depositing an α-Si intrinsic layer during a deposition step, treating the α-Si intrinsic layer to form a treated α-Si intrinsic layer during a plasma treatment step, and sequentially repeating the deposition step and the plasma treatment step until obtaining a desired thickness of the α-Si intrinsic film containing a plurality of treated α-Si intrinsic layers.

### CROSS-REFERENCE TO RELATED APPLICATION

This application claims benefit of U.S. Ser. No. 61/439,190 (APPM/015540L), filed Feb. 3, 2011, which is herein incorporated by reference in its entirety.

### BACKGROUND OF THE INVENTION

1. Field of the Invention

Embodiments of the invention generally relate to methods for forming photovoltaic devices, and more particularly to vapor deposition and plasma treatment processes utilized to form thin film photovoltaic devices.

2. Description of the Related Art

Solar or photovoltaic (PV) cells are devices which convert sunlight into direct current (DC) electrical power. Each individual PV cell generates a specific amount of electrical energy. Therefore, multiple PV cells may be bundled or tiled into a solar module that is scaled to deliver a desired amount of electrical energy.

PV or solar cells typically have one or more p-i-n junctions. When the p-i-n junction of the PV cell is exposed to photons, such as from sunlight, the light is directly converted to electricity through the PV effect. Each p-i-n junction contains three distinct regions within a semiconductor material, where one side is p-doped and denoted as the p-type region, the opposite side is n-doped and denoted as the n-type region, and therebetween, separating the p-type and n-type regions is the intrinsic layer which is denoted as the i-type region.

Silicon, germanium, and Group III/V materials are utilized as semiconductor materials contained within various regions of the p-i-n junction. Several types or phases of silicon materials include amorphous silicon (α-Si), microcrystalline silicon (μc-Si), polycrystalline silicon (poly-Si), and dopant derivatives thereof. Some p-i-n junctions contain silicon in only one phase while other p-i-n junctions contain silicon in a mixture of phases in the various regions.

Some p-i-n junctions contain α-Si materials deposited by chemical vapor deposition (CVD) or plasma-enhanced CVD (PE-CVD) processes. Often, α-Si materials contain impurities, contaminants, and/or various defects upon being deposited as layers within the p-i-n junction during CVD processes. Thermal CVD processes usually form α-Si materials containing more impurities or contaminants due to and derived from the chemical precursors used in thermal CVD processes. Generally, PE-CVD processes provide increased deposition rates for α-Si materials but at a cost of increased defects in the silicon lattice relative to thermal CVD processes. The lattice defects are usually broken Si—Si bonds within the silicon lattice of the α-Si material. Similarly, defects in the silicon lattice are often formed upon plasma exposure of the α-Si material by any of a variety of plasma processes including post deposition plasma anneal step, a plasma clean step, or a plasma doping or implant step.

A PV cell containing a flawed α-Si layer within the p-i-n junction suffers low photoelectric conversion efficiency. Also, such flawed α-Si layer within the p-i-n junction encourages premature failure of the PV cell. Additionally, there is a high production cost associated with the deposition of α-Si materials utilized in PV cells.

Therefore, there is a need for a method to fabricate a PV cell which maximizes the photoelectric conversion efficiency at reduced production costs by depositing α-Si materials containing no or minimal impurities or lattice defects within the p-i-n junction layers.

### SUMMARY OF THE INVENTION

Embodiments of the invention generally provide methods for forming amorphous silicon-based photovoltaic (PV) devices, such as solar or PV cells, by utilizing deposition steps and plasma treatment steps during a plasma-enhanced chemical vapor deposition (PE-CVD) process. The amorphous silicon (α-Si) materials, layers, and films formed by utilizing processes described herein have less lattice defects and impurities relative to α-Si materials formed by previous deposition processes. Therefore, a PV device or cell containing the α-Si materials formed by processes described herein has less premature failure and maximizes the photoelectric conversion efficiency at reduced production costs compared to traditional PV devices. A PE-CVD process is utilized to deposit a layer of α-Si material which is subsequently exposed to a plasma process which removes lattice defects by forming Si—Si bonds within the α-Si lattice. The Si—Si bonds are formed from broken Si bonds or Si atoms in the lattice that remained unbounded during the deposition process. The PE-CVD process includes a sequence of deposition steps and plasma treatment steps generally repeated numerous times to form an amorphous film containing a plurality of plasma-treated silicon layers.

In embodiments described herein, the method includes exposing a transparent conductive oxide (TCO) layer disposed on a substrate to a hydrogen plasma within a processing chamber (e.g., CVD or PE-CVD chamber) during a pretreatment process, forming a p-type α-Si film over the TCO layer, forming an α-Si intrinsic film over the p-type α-Si film during a PE-CVD process, and forming an n-type α-Si film over the α-Si intrinsic film. The method further includes forming the α-Si intrinsic film during the PE-CVD process by depositing an amorphous silicon intrinsic layer during a deposition step and treating the amorphous silicon intrinsic layer to form a treated amorphous silicon intrinsic layer during a plasma treatment step.

The α-Si intrinsic film may contain a single plasma treated α-Si intrinsic layer, but generally contains a plurality of plasma treated α-Si intrinsic layers. In some examples, the plasma treatment step includes exposing the α-Si intrinsic layer to a hydrogen plasma while forming the treated α-Si intrinsic layer. The method further includes sequentially repeating the deposition step and the plasma treatment step while obtaining a desired thickness of the α-Si intrinsic film containing a plurality of treated α-Si intrinsic layers.

In some embodiments, the PE-CVD process also includes flowing a silicon precursor gas and hydrogen gas to the substrate, generating a first plasma by ionizing the silicon precursor gas and the hydrogen gas, and depositing the α-Si intrinsic layer during the deposition step. Subsequently, the PE-CVD process includes generating a second plasma by stopping the flow of the silicon precursor gas to the substrate, maintaining the flow of the hydrogen gas to the substrate, maintaining the ionization of the hydrogen gas, and exposing the α-Si intrinsic layer to the second plasma while forming a treated α-Si intrinsic layer.

In some examples, the deposition step and the plasma treatment step each independently lasts for a time period within a range from about 2 seconds to about 60 seconds. The deposition step and the plasma treatment step are sequentially repeated a predetermined number of times or cycles while forming the α-Si intrinsic film that contains a plurality of treated α-Si intrinsic layers, such as the respective predetermined number of layers. Examples provide that the deposition step and the plasma treatment step are sequentially repeated multiple times or cycles (e.g., 2-12 times or cycles) to form an α-Si intrinsic film having the respective number of treated α-Si intrinsic layers. In some examples, the deposition step and the plasma treatment step are sequentially repeated 6 or 7 times or cycles to form an α-Si intrinsic film having 6 or 7 treated α-Si intrinsic layers. In another example, the deposition step and the plasma treatment step are sequentially repeated 12 times or cycles to form an α-Si intrinsic film having 12 treated α-Si intrinsic layers. The α-Si intrinsic film generally has a thickness within a range from about 500 Å to about 2,000 Å.

In another embodiment, the PE-CVD process for forming the α-Si intrinsic layer generally includes flowing a silicon precursor gas and hydrogen gas to the substrate, generating a first plasma by ionizing the silicon precursor gas and the hydrogen gas, and depositing the α-Si intrinsic layer during the deposition step. Subsequently, the PE-CVD process further includes extinguishing the first plasma by stopping the ionization of the silicon precursor gas and the hydrogen gas, stopping the flow of the silicon precursor gas to the substrate, but maintaining the flow of the hydrogen gas to the substrate during a transition step. Thereafter, the PE-CVD process includes maintaining the flow of the hydrogen gas to the substrate, generating a second plasma by ionizing the hydrogen gas, and exposing the α-Si intrinsic layer to the second plasma while forming a treated α-Si intrinsic layer during the plasma treatment step.

The deposition step, the transition step, and the plasma treatment step may be sequentially repeated a predetermined number of times or cycles while forming an α-Si intrinsic film that contains a plurality of treated α-Si intrinsic layers, such as the respective predetermined number of layers. Examples provide that the deposition step, the transition step, and the plasma treatment step are sequentially repeated multiple times or cycles (e.g., 2-12 times or cycles) to form an α-Si intrinsic film having the respective number of treated α-Si intrinsic layers. In some examples, the plasma power is turned off and the plasma remains extinguished for a time period within a range from about 2 seconds to about 60 seconds during the transition step prior to re-ionizing (or re-igniting) the plasma during the plasma treatment step.

In other embodiments described herein, a method for forming an α-Si-based PV device includes exposing a TCO layer disposed on a substrate to a hydrogen plasma formed by ionizing a stream of hydrogen gas within a processing chamber (e.g., CVD or PE-CVD chamber) during a pretreatment process, forming a p-type α-Si film over the TCO layer within the processing chamber, forming an α-Si intrinsic film over the p-type α-Si film within the processing chamber during a PE-CVD process, and forming an n-type α-Si film over the α-Si intrinsic film within the processing chamber. The method further includes forming the p-type α-Si film by depositing a first p-type silicon layer on the TCO layer by exposing the substrate to a hydrogen plasma, a silicon precursor gas, and a boron precursor gas during a first step, stopping the exposure of the silicon precursor gas and the boron precursor gas to the substrate while exposing the first p-type silicon layer to the hydrogen plasma during a second step, and depositing a second p-type silicon layer on the first p-type silicon layer by exposing the substrate to the hydrogen plasma, the silicon precursor gas, and the boron precursor gas during a third step. The method further includes forming the α-Si intrinsic film over the p-type α-Si film within the processing chamber during a PE-CVD process by depositing an α-Si intrinsic layer during a deposition step, treating the α-Si intrinsic layer to form a treated α-Si intrinsic layer during a plasma treatment step, and sequentially repeating the deposition step and the plasma treatment step while forming the α-Si intrinsic film containing a plurality of treated α-Si intrinsic layers. The method further includes forming the n-type α-Si film by exposing the substrate to the hydrogen plasma, the silicon precursor gas, and a phosphorus precursor gas within the processing chamber.

In one embodiment, the PE-CVD process for forming the α-Si intrinsic layer includes a deposition step and a plasma treatment step. The deposition step of the PE-CVD process includes flowing a silicon precursor gas and hydrogen gas to the substrate, generating a first plasma by ionizing the silicon precursor gas and the hydrogen gas, and depositing the α-Si intrinsic layer. The plasma treatment step of the PE-CVD process includes generating a second plasma by stopping the flow of the silicon precursor gas to the substrate, maintaining the flow of the hydrogen gas to the substrate, and maintaining the ionization of the hydrogen gas while exposing the α-Si intrinsic layer to the second plasma and forming the treated α-Si intrinsic layer.

In another embodiment, the PE-CVD process for forming the α-Si intrinsic layer includes a deposition step, a transition step, and a plasma treatment step. The deposition step of the PE-CVD process includes flowing a silicon precursor gas and hydrogen gas to the substrate, generating a first plasma by ionizing the silicon precursor gas and the hydrogen gas, and depositing the α-Si intrinsic layer. The transition step of the PE-CVD process includes extinguishing the first plasma by stopping the ionization of the silicon precursor gas and the hydrogen gas, stopping the flow of the silicon precursor gas to the substrate, and maintaining the flow of the hydrogen gas to the substrate. The plasma treatment step includes maintaining the flow of the hydrogen gas to the substrate, generating a second plasma by ionizing the hydrogen gas, and exposing the α-Si intrinsic layer to the second plasma while forming the treated α-Si intrinsic layer.

### BRIEF DESCRIPTION OF THE DRAWINGS

So that the manner in which the above recited features in embodiments of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a flow chart depicting a process for forming a photovoltaic cell containing a p-i-n junction, as described by embodiments herein;

FIG. 2A shows a table illustrating some of the process conditions utilized in the process depicted in FIG. 1, as described by one embodiment herein;

FIG. 2B shows another table illustrating additional process conditions utilized in the process depicted in FIG. 1, as described by another embodiment herein; and

FIG. 3 depicts a cross-sectional view of a photovoltaic cell containing a p-i-n junction, as described by embodiments herein.

### DETAILED DESCRIPTION

Embodiments of the invention generally provide methods for forming amorphous silicon-based photovoltaic (PV) devices, such as solar or PV cells, by utilizing deposition steps and plasma treatment steps during a plasma-enhanced chemical vapor deposition (PE-CVD) process.

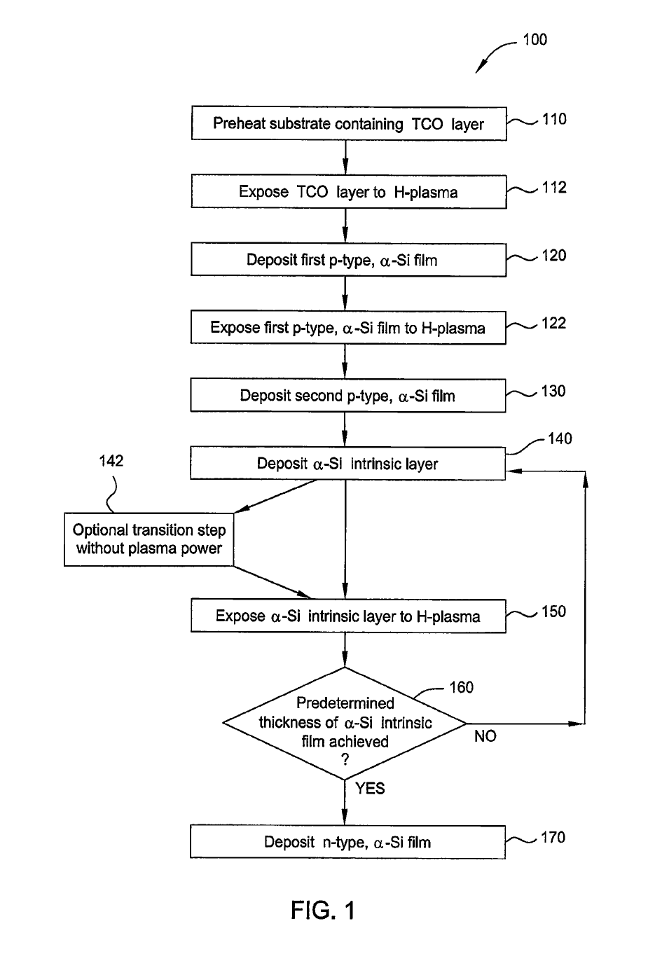

FIG. 1 shows a flow chart depicting process 100, which is utilized to form solar or PV devices or cells containing at least one amorphous silicon (α-Si) p-i-n junction, as described by embodiments herein. In one embodiment, process 100 includes the steps of preheating a substrate having a transparent conductive oxide (TCO) layer disposed thereon at step 110, exposing the TCO layer on the substrate to a hydrogen plasma at step 112, depositing or forming a first p-type, amorphous silicon (α-Si) film on or over the TCO layer at step 120, exposing the first p-type, α-Si film to the hydrogen plasma at step 122, and depositing a second p-type α-Si film on or over the first p-type, α-Si film at step 130.

Process 100 further includes the steps of depositing an α-Si intrinsic layer on or over second p-type α-Si film at step 140 and then optionally maintaining the plasma power and exposing the α-Si intrinsic layer on the substrate to a plasma (e.g., hydrogen plasma) at step 150 or optionally stopping/ceasing the plasma power during a transition step at step 142 prior to exposing the α-Si intrinsic layer on the substrate to a plasma (e.g., hydrogen plasma) at step 150. Subsequently, process 100 includes a conditional step of determining if the desired thickness of the α-Si intrinsic film/layer has been achieved at step 160. If the condition in step 160 is satisfied, that is, the α-Si intrinsic film has been deposited or formed to the desired thickness, then process 100 proceeds to forming an n-type, α-Si film at step 170. However, if the condition in step 160 is not satisfied, that is, the desired thickness of the α-Si intrinsic film has not been achieved, then step 140, optionally step 142, and step 150 are sequentially repeated until the condition of step 160 is satisfied, that is, the desired thickness of the α-Si intrinsic film containing a plurality of α-Si intrinsic layers has been deposited or formed on the substrate.

In some embodiments, the processes conducted during steps 110, 112, 120, 122, 130, 140, 142, 150, and/or 170 are generally conducted in the same processing chamber, such as a CVD, PE-CVD, or plasma chamber. However, the processes conducted during steps 110, 112, 120, 122, 130, 140, 142, 150, and/or 170 are not limited to being conducted in the same processing chamber as other steps. In other embodiments, the processes of steps 140, 142, and 150 are conducted in the same processing chamber as each other and the processes of the steps 110, 112, 120, 122, 130, and/or 170 are each independently conducted in the same processing chamber as in steps 140, 142, and 150 or a different processing chamber. In some examples, the processes of steps 140, 142, and 150 are conducted in a single CVD or PE-CVD chamber and the processes of the steps 110, 112, 120, 122, 130, and 170 are also conducted in the same CVD or PE-CVD chamber.

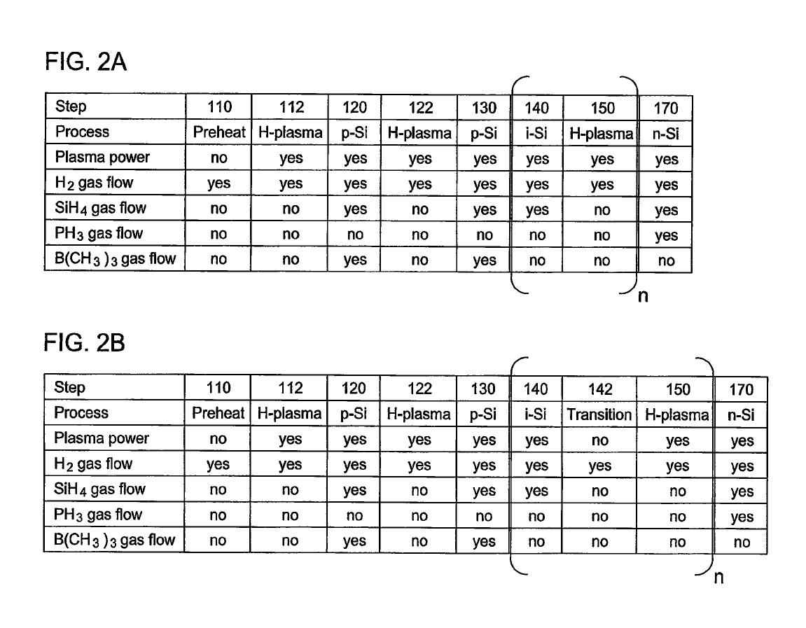

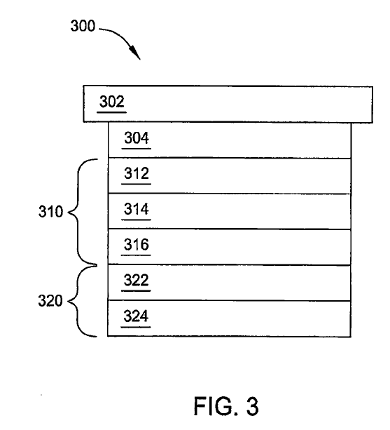

FIGS. 2A-2B show tables illustrating several process conditions utilized during two variations of process 100. The tables in FIGS. 2A-2B depict stages in which the plasma power and the flow of process/precursor gases are activated during the various steps of process 100. The steps 110-130 and 170 are the same steps for both tables in FIGS. 2A-2B. The table in FIG. 2A indicates that steps 140 and 150 are cyclically repeated during process 100 and the table in FIG. 2B indicates that steps 140, 142, and 150 are cyclically repeated during process 100. Each cycle of steps is generally repeated a number of times or cycles—such as at least once or up to about 40 times/cycles or more while forming a desirable thickness of an α-Si intrinsic film. Process 100 is utilized to form single junction, tandem junction, or multi-junction photovoltaic cells. In one example, a single junction photovoltaic cell, such as photovoltaic cell 300 depicted in FIG. 3, is fabricated or otherwise formed by conducting process 100.

FIG. 3 illustrates a cross-sectional view of photovoltaic (PV) cell 300, which is an amorphous silicon-based thin film PV cell having a front window, such as substrate 302, as described in one embodiment herein. In general, PV cell 300 contains a transparent conductive oxide (TCO) layer 304, disposed on substrate 302, a p-i-n junction 310 disposed on TCO layer 304, and a back reflector 320 disposed over p-i-n junction 310. Additionally, p-i-n junction 310 contains a p-type α-Si film 312, an α-Si intrinsic film 314, and an n-type α-Si film 316 and back reflector 320 contains a transparent conductive oxide (TCO) layer 322 and a metallic reflective layer 324. In some embodiments, each film contained within p-i-n junction 310 has a single layer or multiple layers. In one example, p-type α-Si film 312 contains multiple p-type α-Si layers, α-Si intrinsic film 314 contains multiple α-Si intrinsic layers, and n-type α-Si film contains multiple n-type α-Si layers.

During step 110 of process 100, substrate 302 having TCO layer 304 disposed thereon is heated to a process temperature within a processing chamber during a preheat step. TCO layer 304 disposed on substrate 302 is exposed to hydrogen gas within the processing chamber and maintained at a process temperature within a range from about 30° C. to about 300° C., more narrowly within a range from about 100° C. to about 200° C., during step 110. The preheat step generally last for a time period within a range from about 1 second to about 15 seconds, more narrowly within a range from about 2 seconds to about 10 seconds, or from about 3 seconds to about 8 seconds. The hydrogen gas is administered into the processing chamber and exposed to substrate 302 and TCO layer 304 while at a flow rate within a range from about 5 slm (standard liters per minute) to about 100 slm, more narrowly within a range from about 10 slm to about 50 slm, and more narrowly within a range from about 20 slm to about 40 slm, for example, about 30 slm. In one example, TCO layer 304 disposed on substrate 302 is exposed to hydrogen gas at 30 slm within the processing chamber and heated to a temperature of about 200° C. or less for about 5 seconds.

At step 112, TCO layer 304 disposed on substrate 302 is exposed to a hydrogen plasma within the processing chamber during a plasma pretreatment. A process gas containing hydrogen gas is ignited or ionized to generate a hydrogen plasma. In many examples, the process gas only contains hydrogen gas or substantially contains hydrogen gas. In other examples, the process gas contains hydrogen gas and a carrier gas, such as argon, helium, neon, nitrogen, or mixtures thereof. The gas flow rate of the hydrogen gas may be the same in step 112 as in step 110 or is adjusted to have a different gas flow rate. Therefore, in step 112, the hydrogen gas generally has a flow rate within a range from about 5 slm to about 100 slm, more narrowly within a range from about 10 slm to about 50 slm, and more narrowly within a range from about 20 slm to about 40 slm, for example, about 30 slm.

An RF power source or other plasma power source is generally provided to the showerhead or other process region within the processing chamber during the plasma pretreatment at step 112. The substrate and/or the support/pedestal is biased during the ionization of a plasma some examples herein. The plasma power is generally set at a power level or power set point within a range from about 1,800 watts to about 3,500 watts, more narrowly within a range from about 2,200 watts to about 3,200 watts, more narrowly within a range from about 2,600 watts to about 3,000 watts, for example, about 2,800 watts. Plasma power sources utilized during plasma processes (e.g., plasma treatment and/or plasma deposition) described herein are usually RF power sources, which include VHF (very high frequency) power sources, MW (microwave) power sources, and other frequencies. The processing chamber may have an internal pressure during the plasma pretreatment within a range from about 0.1 Torr to about 10 Torr, more narrowly within a range from about 0.5 Torr to about 5 Torr, and more narrowly within a range from about 1 Torr to about 5 Torr, for example, about 3 Torr. In some examples, In some examples, the spacing between the top surface of PV cell 300 disposed on the substrate receiving surface and the showerhead within the processing chamber is within a range from about 200 mil (about 5.1 mm) to about 1,200 mil (about 30.5 mm), more narrowly within a range from about 400 mil (about 10.2 mm) to about 800 mil (about 20.3 mm), for example, about 600 mil (about 15.2 mm) during step 112. The plasma pretreatment generally last for a time period within a range from about 5 seconds to about 30 seconds, more narrowly within a range from about 10 seconds to about 20 seconds, or from about 12 seconds to about 18 seconds, for example, about 15 seconds. In one example, TCO layer 304 on substrate 302 is exposed to hydrogen plasma for about 15 seconds within the processing chamber during step 112.

During step 120 of process 100, p-type α-Si film 312 is deposited or otherwise formed on TCO layer 304 within the processing chamber. In some embodiments, p-type α-Si film 312 is formed by depositing multiple p-type α-Si layers on or over TCO layer 304. A deposition gas containing a silicon precursor gas, a p-type dopant gas (e.g., a boron precursor gas), and hydrogen gas is ionized (or ignited) to form or otherwise generate while depositing a p-type material, such as p-type α-Si film 312, during a PE-CVD process.

A suitable silicon precursor is generally gasified and used as a silicon precursor gas. Exemplary silicon precursors include silane (SiH₄), disilane (Si₂H₆), silicon tetrafluoride (SiF₄), silicon tetrachloride (SiCl₄), dichlorosilane (SiH₂Cl₂), derivatives thereof, or combinations thereof. Suitable p-type dopants utilized to form p-type materials contained within p-type α-Si film 312 include Group III elements, such as boron, aluminum, or combinations thereof. Boron is often utilized as the p-type dopant element. A boron precursor is gasified to form a boron precursor gas that is utilized as a p-type dopant gas. Exemplary boron precursors include trimethylboron (TMB (or B(CH₃)₃)), triethylboron (B(CH₂CH₃)₃), diborane (B₂H₆), trifluoroborane (BF₃), complexes thereof, or derivatives thereof. An aluminum precursor is gasified to form an aluminum precursor gas that is utilized as a p-type dopant gas. Exemplary aluminum precursors include alkyl aluminum compounds, such as trimethylaluminum (TMA (or Al(CH₃)₃)), triethylaluminum (Al(CH₂CH₃)₃), dimethylaluminum (DMA (or (H)Al(CH₃)₂)), diethylaluminum ((H)Al(CH₂CH₃)₂), complexes thereof, or derivatives thereof. In one example, TMB is a dopant precursor utilized to form a p-type material contained within p-type α-Si film 312. In another example, TMA is a dopant precursor utilized to form a p-type material contained within p-type α-Si film 312.

In step 120, the silicon precursor gas generally has a flow rate within a range from about 1 slm to about 12 slm, more narrowly within a range from about 2 slm to about 10 slm, and more narrowly within a range from about 3 slm to about 8 slm, for example, about 4.8 slm. The boron precursor gas generally has a flow rate within a range from about 2 slm to about 20 slm, more narrowly within a range from about 5 slm to about 15 slm, and more narrowly within a range from about 8 slm to about 12 slm, for example, about 10 slm. The hydrogen gas generally has a flow rate within a range from about 50 slm to about 200 slm, more narrowly within a range from about 80 slm to about 160 slm, and more narrowly within a range from about 100 slm to about 140 slm, for example, about 120 slm.

An RF power source or other plasma power source is generally provided to the showerhead or other process region within the processing chamber during the plasma deposition at step 120. The plasma power is generally set at a power level or power set point within a range from about 1,000 watts to about 2,200 watts, more narrowly within a range from about 1,200 watts to about 2,000 watts, and more narrowly within a range from about 1,400 watts to about 1,800 watts, for example, about 1,600 watts. Plasma power sources utilized during plasma processes (e.g., plasma treatment and/or plasma deposition) described herein are usually RF power sources, which include VHF power sources, MW power sources, and other frequencies. The internal pressure of the processing chamber during the plasma deposition is usually maintained at a pressure within a range from about 0.1 Torr to about 10 Torr, more narrowly within a range from about 0.5 Torr to about 5 Torr, and more narrowly within a range from about 1 Torr to about 5 Torr, for example, about 3 Torr. In some examples, the spacing between the top surface of PV cell 300 disposed on the substrate receiving surface and the showerhead within the processing chamber is generally within a range from about 200 mil (about 5.1 mm) to about 1,200 mil (about 30.5 mm), more narrowly within a range from about 400 mil (about 10.2 mm) to about 800 mil (about 20.3 mm), for example, about 600 mil (about 15.2 mm) during step 120. The plasma deposition generally last for a time period within a range from about 10 seconds to about 40 seconds, more narrowly within a range from about 15 seconds to about 30 seconds, or from about 20 seconds to about 25 seconds, for example, about 23 seconds. In one example, TCO layer 304 disposed on substrate 302 is exposed to the deposition plasma containing the silicon precursor gas, the boron precursor gas, and the hydrogen gas for about 23 seconds within the processing chamber during step 120.

Thereafter, substrate 302 containing p-type α-Si film 312 is exposed to the hydrogen plasma within the processing chamber during a plasma treatment during step 122. A process gas containing hydrogen gas is ionized (or ignited) to form or otherwise generate a hydrogen plasma. In many examples, the process gas contains only hydrogen gas or substantially contains hydrogen gas. In other examples, the process gas contains hydrogen gas and a carrier gas, such as argon, helium, neon, nitrogen, or mixtures thereof. The hydrogen gas generally has a flow rate within a range from about 5 slm to about 100 slm, more narrowly within a range from about 10 slm to about 50 slm, and more narrowly within a range from about 20 slm to about 40 slm, for example, about 30 slm.

The plasma power is generally set at a power level or power set point within a range from about 1,800 watts to about 3,500 watts, more narrowly within a range from about 2,200 watts to about 3,200 watts, more narrowly within a range from about 2,600 watts to about 3,000 watts, for example, about 2,800 watts. Plasma power sources utilized during plasma processes (e.g., plasma treatment and/or plasma deposition) described herein are usually RF power sources, which include VHF power sources, MW power sources, and other frequencies. The internal pressure of the processing chamber during the hydrogen plasma treatment is generally maintained at a pressure within a range from about 0.1 Torr to about 10 Torr, more narrowly within a range from about 0.5 Torr to about 5 Torr, and more narrowly within a range from about 1 Torr to about 5 Torr, for example, about 3 Torr. In some examples, the spacing between the top surface of PV cell 300 disposed on the substrate receiving surface and the showerhead within the processing chamber is within a range from about 200 mil (about 5.1 mm) to about 1,200 mil (about 30.5 mm), more narrowly within a range from about 400 mil (about 10.2 mm) to about 800 mil (about 20.3 mm), for example, about 600 mil (about 15.2 mm) during step 122. The hydrogen plasma treatment generally last for a time period within a range from about 5 seconds to about 30 seconds, more narrowly within a range from about 10 seconds to about 20 seconds, or from about 12 seconds to about 18 seconds, for example, about 15 seconds. In one example, TCO layer 304 disposed on substrate 302 is exposed to hydrogen plasma for about 15 seconds within the processing chamber during step 122.

During step 130 of process 100, an additional p-type α-Si material is deposited on p-type α-Si film 312 within the processing chamber. The deposition gas containing the silicon precursor gas, the p-type dopant gas (e.g., the boron precursor gas), and hydrogen gas is ignited or ionized to generate or otherwise form a plasma while depositing the p-type α-Si material to further form or deposit p-type α-Si film 312 by PE-CVD during step 130. Therefore, p-type α-Si film 312 may contain two of more films or layers formed during steps 120, 122, and 130. The same deposition gas components and deposition process perimeters may be utilized as in step 130 as utilized in step 120, or alternatively, different deposition gas components or deposition process perimeters may be utilized as in step 130 as utilized in step 120. In one example, p-type α-Si film 312 contains a first p-type α-Si film or layer deposited in step 120 and plasma treated in step 122 and a second p-type α-Si film or layer deposited in step 130, whereas the first p-type α-Si film or layer and the second p-type α-Si film or layer have the same composition or substantially the same composition. In one example, p-type α-Si film 312 contains the first p-type α-Si film or layer with a different composition as the second p-type α-Si film or layer.

In step 130, the silicon precursor gas generally has a flow rate within a range from about 1 slm to about 12 slm, more narrowly within a range from about 2 slm to about 10 slm, and more narrowly within a range from about 3 slm to about 8 slm, for example, about 4.8 slm. The boron precursor gas generally has a flow rate within a range from about 2 slm to about 20 slm, more narrowly within a range from about 5 slm to about 15 slm, and more narrowly within a range from about 8 slm to about 12 slm, for example, about 10 slm. The hydrogen gas generally has a flow rate within a range from about 50 slm to about 200 slm, more narrowly within a range from about 80 slm to about 160 slm, and more narrowly within a range from about 100 slm to about 140 slm, for example, about 130 slm.

The RF power source or other plasma power source is generally provided to the showerhead or other process region within the processing chamber during the plasma deposition at step 130. The plasma power is generally set at a power level or power set point within a range from about 1,000 watts to about 2,200 watts, more narrowly within a range from about 1,200 watts to about 2,000 watts, more narrowly within a range from about 1,400 watts to about 1,800 watts, for example, about 1,600 watts. Plasma power sources utilized during plasma processes (e.g., plasma treatment and/or plasma deposition) described herein are usually RF power sources, which include VHF power sources, MW power sources, and other frequencies. The internal pressure of the processing chamber during the plasma deposition is generally maintained at a pressure within a range from about 0.1 Torr to about 10 Torr, more narrowly within a range from about 0.5 Torr to about 5 Torr, and more narrowly within a range from about 1 Torr to about 5 Torr, for example, about 3 Torr. In some examples, the spacing between the top surface of PV cell 300 disposed on the substrate receiving surface and the showerhead within the processing chamber is within a range from about 200 mil (about 5.1 mm) to about 1,200 mil (about 30.5 mm), more narrowly within a range from about 400 mil (about 10.2 mm) to about 800 mil (about 20.3 mm), for example, about 600 mil (about 15.2 mm) during step 130. The plasma deposition generally last for a time period within a range from about 10 seconds to about 40 seconds, more narrowly within a range from about 15 seconds to about 30 seconds, or from about 20 seconds to about 25 seconds, for example, about 23 seconds. In one example, TCO layer 304 disposed on substrate 302 is exposed to the deposition plasma containing the silicon precursor gas, the boron precursor gas, and the hydrogen gas for about 23 seconds within the processing chamber during step 130.

Steps 140-160 are process steps which may be conducted once or repeated as many times as necessary to deposit or form α-Si intrinsic film 314 at a predetermined or desired thickness. A single α-Si intrinsic layer is deposited on or over p-type α-Si film 312 within a processing chamber during step 140 and subsequently, the α-Si intrinsic layer is exposed to a hydrogen plasma to form a treated α-Si intrinsic layer during step 150. Step 142 is an optional step and may be conducted or omitted between steps 140 and 150. In one example, process 100 includes the step of maintaining the plasma power on from step 140 while exposing the deposited α-Si intrinsic layer on the substrate to a plasma (e.g., hydrogen plasma) at step 150. In another example, process 100 includes the step of stopping/ceasing the plasma power of step 140 during a transition step at step 142 prior to exposing the deposited α-Si intrinsic layer to a plasma (e.g., hydrogen plasma) at step 150. In one example, steps 140 and 150 are each conducted once to form α-Si intrinsic film 314 containing a single, treated α-Si intrinsic layer of desired thickness. In other examples, steps 140, 142, and 150 are each conducted once to form α-Si intrinsic film 314 containing a single, treated α-Si intrinsic layer of desired thickness.

Subsequently, process 100 includes a conditional step of determining if the desired thickness of α-Si intrinsic film 314 has been achieved at step 160. If the condition in step 160 is satisfied, that is, α-Si intrinsic film 314 has been deposited or formed to the desired thickness, then process 100 proceeds to depositing or forming an n-type, α-Si film. However, if the condition in step 160 is not satisfied, that is, the desired thickness of α-Si intrinsic film 314 has not been achieved, then process 100 proceeds by repeating steps 140 and 150 or by repeating steps 140, 142, and 150 until the condition of step 160 is satisfied, that is, the desired thickness of α-Si intrinsic film 314 containing a plurality of α-Si intrinsic layers has been deposited or formed on the substrate.

The tables in FIGS. 2A-2B illustrate stages in which the plasma power and the flow of process/precursor gases are activated during the various steps of process 100. The table in FIG. 2A indicates that steps 140 and 150 are sequentially repeated “n” times or cycles during process 100 as described by one embodiment. The table in FIG. 2B indicates that steps 140, 142, and 150 are repeated “n” times or cycles during process 100 as described by another embodiment. In both embodiments, the “n” is the number of times or cycles the steps are repeated during process 100. The “n” is equal to any integer, for example, the integer “n” is generally within a range from 1 to about 80, more narrowly within a range from 1 to about 40, more narrowly within a range from 2 to about 20, more narrowly within a range from 3 to about 15, and more narrowly within a range from about 4 to about 12, and more narrowly within a range from about 5 to about 10, for example, about 6 or about 7. However, step 142, as depicted in FIG. 1, may be conducted or omitted during each independent cycle of steps 140-160. Therefore, step 142 may be conducted the same amount of times as steps 140 and 150 or conducted less amount of times as steps 140 and 150.

In some examples, the transition step at step 142 is omitted during each cycle of steps while only steps 140 and 150 are sequentially repeated “n” times or cycles during process 100. In other examples, the transition step at step 142 is conducted during each cycle of steps while steps 140, 142, and 150 are sequentially repeated “n” times or cycles during process 100. In additional examples, the transition step at step 142 is intermittently conducted between cycles of steps 140 and 150 or intermittently omitted between cycles of steps 140, 142, and 150 during process 100.

Therefore, in one embodiment, process 100 includes the deposition step (step 140) for depositing an α-Si intrinsic layer and the hydrogen-plasma treatment step (step 150) for forming a treated α-Si intrinsic layer. The deposition and hydrogen-plasma treatment steps are sequentially repeated (e.g., 6, 7, or more times) to form amorphous silicon intrinsic film 314 having the respective amount of treated α-Si intrinsic layers (e.g., 6, 7, or more treated layers). In another embodiment, process 100 includes the deposition step (step 140) for depositing an α-Si intrinsic layer, the transition step (step 142) for extinguishing the plasma, and the hydrogen-plasma treatment step (step 150) for igniting the plasma and forming a treated α-Si intrinsic layer. The deposition, transition, and hydrogen-plasma treatment steps are repeated (e.g., 6, 7, or more times) to form amorphous silicon intrinsic film 314 having the respective amount of treated α-Si intrinsic layers (e.g., 6, 7, or more treated layers). The amorphous silicon intrinsic film 314 generally has a thickness within a range from about 500 Å to about 2,000 Å.

During step 140 of process 100, α-Si intrinsic film 314 is deposited or otherwise formed on p-type α-Si film 312 within the processing chamber. The α-Si intrinsic film 314 contains an α-Si intrinsic material formed a deposition gas during a PE-CVD process. The deposition gas contains a silicon precursor gas and hydrogen gas and is ignited or otherwise ionized to generate a plasma while depositing the α-Si intrinsic material. Exemplary silicon precursors utilized in step 140 include silane (SiH₄), disilane (Si₂H₆), silicon tetrafluoride (SiF₄), silicon tetrachloride (SiCl₄), dichlorosilane (SiH₂Cl₂), derivatives thereof, or combinations thereof.

In step 140, the silicon precursor gas generally has a flow rate within a range from about 0.5 slm to about 10 slm, more narrowly within a range from about 1 slm to about 8 slm, and more narrowly within a range from about 1.5 slm to about 5 slm, for example, about 2.3 slm. The hydrogen gas generally has a flow rate within a range from about 5 slm to about 100 slm, more narrowly within a range from about 10 slm to about 60 slm, and more narrowly within a range from about 20 slm to about 40 slm, for example, about 28 slm. The plasma power is generally set at a power level or power set point within a range from about 1,800 watts to about 3,500 watts, more narrowly within a range from about 2,000 watts to about 3,000 watts, more narrowly within a range from about 2,200 watts to about 2,600 watts, for example, about 2,400 watts. Plasma power sources utilized during plasma processes (e.g., plasma treatment and/or plasma deposition) described herein are usually RF power sources, which include VHF power sources, MW power sources, and other frequencies. The internal pressure of the processing chamber during the plasma deposition is generally maintained at a pressure within a range from about 0.1 Torr to about 10 Torr, more narrowly within a range from about 0.5 Torr to about 5 Torr, and more narrowly within a range from about 1 Torr to about 5 Torr, for example, about 2.5 Torr. In some examples, the spacing between the top surface of PV cell 300 disposed on the substrate receiving surface and the showerhead within the processing chamber is within a range from about 200 mil (about 5.1 mm) to about 1,200 mil (about 30.5 mm), more narrowly within a range from about 400 mil (about 10.2 mm) to about 800 mil (about 20.3 mm), for example, about 600 mil (about 15.2 mm) during step 140.

The plasma deposition during step 140 generally last for a time period within a range from about 2 seconds to about 5 minutes, more narrowly within a range from about 3 seconds to about 2 minutes, more narrowly within a range from about 5 seconds to about 2 minutes. In some specific examples, the plasma deposition during step 140 generally last for a time period within a range from about 2 seconds to about 60 seconds, more narrowly within a range from about 10 seconds to about 60 seconds, more narrowly within a range from about 15 seconds to about 40 seconds, or from about 20 seconds to about 30 seconds, for example, about 25 seconds. In one example, p-type α-Si film 312 disposed on substrate 302 is exposed to the deposition plasma formed from the silicon precursor gas and the hydrogen gas while depositing or otherwise forming α-Si intrinsic film 314 within the processing chamber during step 140.

In some embodiments of process 100, the optional transition step 142 is skipped/omitted and step 150 is started directly after the completion of step 140 and in other embodiments, the optional transition step 142 is implemented during the transition between steps 140 and 150. FIG. 2A depicts a table of exemplary process perimeters utilized during process 100 that excludes the optional step 142. The PE-CVD process utilized during process 100 includes the deposition step of step 140 and the plasma treatment step of step 150 (and skips the transition step of step 142). In one example, step 140 includes flowing a silicon precursor gas and hydrogen gas to the substrate, generating a first plasma by ionizing the silicon precursor gas and the hydrogen gas, and depositing the α-Si intrinsic layer. Step 150 includes generating a second plasma by stopping the flow of the silicon precursor gas to the substrate, maintaining the flow of the hydrogen gas to the substrate, and maintaining the ionization of the hydrogen gas and then exposing the α-Si intrinsic layer to the second plasma while forming the treated α-Si intrinsic layer.

Therefore, the plasma power is maintained on, the flow of hydrogen gas flow is maintained, and the flow of the silicon precursor gas (e.g., SiH₄) is stopped in one example during the transition from step 140 to step 150. The power level of the plasma power and the gas flow rate of the hydrogen gas may be adjusted during the transition from step 140 to step 150. In one example, the plasma power is increased from about 2,400 watts to about 2,800 watts and the gas flow rate of the hydrogen gas is increased from about 28 slm to about 30 slm during the transition from step 140 to step 150.

FIG. 2B depicts a table of exemplary process perimeters utilized during process 100 which includes the optional step 142. The PE-CVD process utilized during process 100 includes the deposition step of step 140, the transition step of step 142, and the plasma treatment step of step 150. In one example, step 140 includes flowing a silicon precursor gas and hydrogen gas to the substrate, generating a first plasma by ionizing the silicon precursor gas and the hydrogen gas, and depositing the α-Si intrinsic layer. Step 142 includes extinguishing the first plasma by stopping the ionization of the silicon precursor gas and the hydrogen gas, stopping the flow of the silicon precursor gas to the substrate, and maintaining the flow of the hydrogen gas to the substrate. Step 150 includes maintaining the flow of the hydrogen gas to the substrate, generating a second plasma by ionizing the hydrogen gas, and exposing the α-Si intrinsic layer to the second plasma while forming the treated α-Si intrinsic layer. Therefore, the plasma power is ceased or otherwise stopped, the flow of hydrogen gas flow is maintained, and the flow of the silicon precursor gas (e.g., SiH₄) is stopped in one example during step 142. The gas flow rate of the hydrogen gas may be adjusted during or for step 142. In some examples, the gas flow rate of the hydrogen gas is increased from about 28 slm to about 30 slm during step 142.

The plasma power is ceased, extinguished, or otherwise stopped during the transition step while the gas flow of hydrogen gas and/or other gases may continue to flow through the processing chamber towards the substrate during step 142. Generally, the plasma power remains ceased, extinguished, or otherwise stopped for a time period within a range from about 2 seconds to about 5 minutes, more narrowly within a range from about 3 seconds to about 2 minutes, more narrowly within a range from about 5 seconds to about 2 minutes during the transition step. In some specific examples, the ceased, extinguished, or otherwise stopped plasma power during step 142 generally last for a time period within a range from about 2 seconds to about 60 seconds, more narrowly within a range from about 10 seconds to about 60 seconds, more narrowly within a range from about 15 seconds to about 40 seconds, or from about 20 seconds to about 30 seconds, for example, about 25 seconds.

Thereafter, each α-Si intrinsic layer of α-Si intrinsic film 314 is exposed to the hydrogen plasma within the processing chamber during a plasma treatment at step 150. A process gas containing hydrogen gas is ignited or ionized to generate or otherwise form a hydrogen plasma. In many examples, the process gas contains only hydrogen gas or substantially contains hydrogen gas. In other examples, the process gas contains hydrogen gas and a carrier gas, such as argon, helium, neon, nitrogen, or mixtures thereof. The hydrogen gas generally has a flow rate within a range from about 5 slm to about 100 slm, more narrowly within a range from about 10 slm to about 50 slm, and more narrowly within a range from about 20 slm to about 40 slm, for example, about 30 slm.

The plasma power is generally set at a power level or power set point within a range from about 1,800 watts to about 3,500 watts, more narrowly within a range from about 2,200 watts to about 3,200 watts, more narrowly within a range from about 2,600 watts to about 3,000 watts, for example, about 2,800 watts. The internal pressure of the processing chamber during the hydrogen plasma treatment is generally maintained at a pressure within a range from about 0.1 Torr to about 10 Torr, more narrowly within a range from about 0.5 Torr to about 5 Torr, and more narrowly within a range from about 1 Torr to about 5 Torr, for example, about 2.5 Torr. In some examples, the spacing between the top surface of PV cell 300 disposed on the substrate receiving surface and the showerhead within the processing chamber is within a range from about 200 mil (about 5.1 mm) to about 1,200 mil (about 30.5 mm), more narrowly within a range from about 400 mil (about 10.2 mm) to about 800 mil (about 20.3 mm), for example, about 600 mil (about 15.2 mm) during step 150.

The hydrogen plasma treatment during step 150 generally last for a time period within a range from about 2 seconds to about 5 minutes, more narrowly within a range from about 3 seconds to about 2 minutes, more narrowly within a range from about 5 seconds to about 1 minute. In some specific examples, the hydrogen plasma treatment during step 150 generally last for a time period within a range from about 2 seconds to about 60 seconds, more narrowly within a range from about 5 seconds to about 30 seconds, more narrowly within a range from about 10 seconds to about 20 seconds, or from about 12 seconds to about 18 seconds, for example, about 15 seconds. In one example, α-Si intrinsic film 314 disposed on substrate 302 is exposed to hydrogen plasma for about 15 seconds within the processing chamber during step 150.

During step 170 of process 100, an n-type α-Si film 316 is deposited or otherwise formed on α-Si intrinsic film 314 within the processing chamber. A deposition gas containing a silicon precursor gas, an n-type dopant gas (e.g., a phosphorous precursor gas), and hydrogen gas is ignited or ionized to generate or otherwise form a plasma while forming an n-type material, such as n-type α-Si film 316, during a PE-CVD process.

The silicon precursor is generally gasified and used as a silicon precursor gas. Exemplary silicon precursors include silane (SiH₄), disilane (Si₂H₆), silicon tetrafluoride (SiF₄), silicon tetrachloride (SiCl₄), dichlorosilane (SiH₂Cl₂), derivatives thereof, or combinations thereof. Suitable n-type dopants which may be utilized to form n-type materials contained within n-type α-Si film 316 may include one or more Group V elements, such as phosphorous, arsenic, antimony, or combinations thereof. Phosphorous is used as an n-type dopant element in many examples. A phosphorous precursor is gasified to form a phosphorous precursor gas that is utilized as an n-type dopant gas. Exemplary phosphorous precursors include phosphine (PH₃), methylphosphine (CH₃PH₂), dimethylphosphine ((CH₃)₂PH), trimethylphosphine (TMP or (CH₃)₃P), dimethylphosphine chloride ((CH₃)₂PCl), trichlorophosphine (Cl₃P), complexes thereof, or derivatives thereof. An arsenic precursor is gasified to form an arsenic precursor gas which is also utilized as an n-type dopant gas. An exemplary arsenic precursor includes arsine (ArH₃), complexes thereof, or derivatives thereof. In one example, phosphine is utilized as the n-type dopant.

In step 170, the silicon precursor gas generally has a flow rate within a range from about 1 slm to about 12 slm, more narrowly within a range from about 2 slm to about 10 slm, and more narrowly within a range from about 3 slm to about 8 slm, for example, about 4.8 slm. The phosphorous precursor gas generally has a flow rate within a range from about 2 slm to about 20 slm, more narrowly within a range from about 5 slm to about 15 slm, and more narrowly within a range from about 8 slm to about 12 slm, for example, about 10 slm. The hydrogen gas generally has a flow rate within a range from about 50 slm to about 200 slm, more narrowly within a range from about 80 slm to about 160 slm, and more narrowly within a range from about 100 slm to about 140 slm, for example, about 120 slm.

An RF power source or other plasma power source is generally provided to the showerhead or other process region within the processing chamber during the plasma deposition at step 170. The plasma power is generally set at a power level or power set point within a range from about 1,000 watts to about 4,000 watts, more narrowly within a range from about 2,400 watts to about 3,600 watts, more narrowly within a range from about 2,800 watts to about 3,400 watts, for example, about 3,200 watts. The internal pressure of the processing chamber during the plasma deposition is generally maintained at a pressure within a range from about 0.1 Torr to about 10 Torr, more narrowly within a range from about 0.5 Torr to about 5 Torr, and more narrowly within a range from about 1 Torr to about 5 Torr, for example, about 1.5 Torr. In some examples, the spacing between the top surface of PV cell 300 disposed on the substrate receiving surface and the showerhead within the processing chamber is within a range from about 200 mil (about 5.1 mm) to about 1,200 mil (about 30.5 mm), more narrowly within a range from about 400 mil (about 10.2 mm) to about 800 mil (about 20.3 mm), for example, about 600 mil (about 15.2 mm) during step 170. The plasma deposition generally last for a time period within a range from about 10 seconds to about 40 seconds, more narrowly within a range from about 15 seconds to about 30 seconds, or from about 20 seconds to about 25 seconds, for example, about 23 seconds. In one example, TCO layer 304 disposed on substrate 302 is exposed to the deposition plasma containing the silicon precursor gas, the phosphorous precursor gas, and the hydrogen gas for about 23 seconds within the processing chamber during step 170.

Subsequent to step 170, PV cell 300 contains substrate 302, TCO layer 304, and p-i-n junction 310, and may be separated from the susceptor in the processing chamber during a process lift technique. The process spacing between the showerhead and PV cell 300 is increased while PV cell 300 is exposed to a hydrogen plasma during the process lift technique. In one embodiment, the process lift technique may be a multi-step process, such as a two-step process, wherein the process spacing is adjusted from a first spacing to a second spacing during a first step and subsequently, adjusting from the second spacing to a third spacing during a second step. In one example, the first spacing is within a range from about 200 mil (about 5.1 mm) to about 1,200 mil (about 30.5 mm), more narrowly within a range from about 400 mil (about 10.2 mm) to about 800 mil (about 20.3 mm), for example, about 600 mil (about 15.2 mm); the second spacing is within a range from about 800 mil (about 20.3 mm) to about 3,000 mil (about 76 mm), more narrowly within a range from about 1,200 mil (about 30.4 mm) to about 1,800 mil (about 45.6 mm), for example, about 1,400 mil (about 35.6 mm); and the third spacing is within a range from about 1,000 mil (about 25.4 mm) to about 10,000 mil (about 254 mm), more narrowly within a range from about 4,000 mil (about 102 mm) to about 8,000 mil (about 203 mm), for example, about 6,000 mil (about 152 mm).

The plasma treatment during the first step of the process lift generally last for a time period within a range from about 0.5 seconds to about 20 seconds, more narrowly within a range from about 1 second to about 5 seconds, or from about 2 seconds to about 4 seconds, for example, about 3 seconds. The plasma treatment during the second step of the process lift generally last for a time period within a range from about 0.5 seconds to about 20 seconds, more narrowly within a range from about 1 second to about 10 seconds, or from about 3 seconds to about 7 seconds, for example, about 5 seconds. In one example, PV cell 300 is exposed to hydrogen plasma for about 3 seconds and then about 5 seconds during the first and second steps of the process lift, respectively.

The hydrogen plasma is formed by ionizing (e.g., igniting) a process gas containing hydrogen gas during the first and second steps of the process lift. In many examples, the process gas contains only hydrogen gas or substantially contains hydrogen gas. In other examples, the process gas contains hydrogen gas and a carrier gas, such as argon, helium, neon, nitrogen, or mixtures thereof. In some examples, the gas flow rate of the hydrogen gas is within a range from about 5 slm to about 100 slm, more narrowly within a range from about 10 slm to about 50 slm, and more narrowly within a range from about 20 slm to about 40 slm, for example, about 30 slm. An RF power source or other plasma power source is generally provided to the showerhead or other process region within the processing chamber to form the plasma during the process lift. The plasma power is generally set at a power level or power set point within a range from about 1,800 watts to about 3,500 watts, more narrowly within a range from about 2,400 watts to about 3,400 watts, more narrowly within a range from about 2,800 watts to about 3,200 watts, for example, about 3,000 watts. The internal pressure of the processing chamber during the plasma treatment is generally maintained at a pressure within a range from about 0.1 Torr to about 10 Torr, more narrowly within a range from about 0.5 Torr to about 5 Torr, and more narrowly within a range from about 1 Torr to about 5 Torr, for example, about 1.5 Torr.

Subsequent the process lift step, back reflector 320 is formed over p-i-n junction 310 of PV cell 300. In some embodiments, the transparent conductive oxide (TCO) layer 322 is formed on or over n-type α-Si film 316 of p-i-n junction 310. Thereafter, the metallic reflective layer 324 is formed on or over TCO layer 322 to complete back reflector 320.

The plasma generated and utilized in any of the plasma processes described in process 100, such as CVD, PE-CVD, and plasma treatment processes, may be formed inside of the processing chamber, such as an in situ plasma, or may be formed outside of the processing chamber, such as with a remote plasma system (RPS), and transferred into the processing chamber. The processes conducted during steps 110, 112, 120, 122, 130, 140, 142, 150, and/or 170 are generally conducted in the same processing chamber, such as a CVD, PE-CVD, or plasma chamber, but are not limited to being conducted in the same processing chamber. The processing chamber includes deposition chambers, plasma chambers, and other chambers containing and/or in fluid communication with a plasma source, such as an RPS. The types of processing chambers that may be utilized to conduct the plasma treatment include, but are not limited to CVD chambers, PE-CVD chambers, and plasma chambers. In some examples, an RPS that generates a plasma is coupled with and in fluid communication to a deposition chamber, such as a thermal CVD chamber. Other variations of CVD or deposition chambers that ionize, generate, provide, or otherwise form a plasma during the CVD process may also be utilized during the plasma treatments described herein.

A single processing chamber or multiple processing chambers may be used to conduct the deposition processes (e.g., thermal CVD or PE-CVD) and plasma treatment processes (e.g., VHF or RF) described herein. Exemplary processing chambers include the PECVD 5.7™ chamber and the ATON™ CVD chamber, both manufactured by Applied Materials, Inc., located in Santa Clara, Calif., and an exemplary processing system is the SUNFAB™ solar module production line, also available from Applied Materials, Inc. Additional disclosure of deposition, plasma treatment, and other processing chambers and systems, as well as deposition and plasma treatment processes, and other processes utilized in the manufacturing of photovoltaic/solar devices and cells, as described herein, may be found in the commonly assigned U.S. Pat. Nos. 7,582,515 and 7,655,542, and U.S. application Ser. No. 12/178,289, filed Jul. 23, 2008, and published as U.S. Pub. No. 2009-0020154; U.S. application Ser. No. 12/564,697, filed Sep. 22, 2009, and published as U.S. Pub. No. 2010-0073011; and U.S. application Ser. No. 12/729,777, filed Mar. 23, 2010, and published as U.S. Pub. No. 2011-0232753, which are incorporated by reference in their entirety to the extent not inconsistent with embodiments of the present disclosure.

FIG. 3 depicts an exemplary cross-sectional view of a PV cell 300, such as an amorphous silicon-based thin film photovoltaic cell, in accordance with one embodiment of the invention. PV cell 300 has a front window or transparent substrate, such as substrate 302. Substrate 302 contains a transparent material and may be a thin sheet of glass, quartz, silicon, silicon oxide, plastic or polymeric material (e.g., polycarbonate), or other suitable material. In one embodiment, substrate 302 is a transparent substrate. Substrate 302 generally has a surface area greater than about 0.1 m², such as greater than about 1 m², and greater than about 2 m². It is to be understood that substrate 302 may be referred to as a ‘superstrate’ in which the solar cell is fabricated from the top down. During fabrication, substrate 302 is typically referred to as a substrate, but then referred to as a ‘superstrate’ once the final product is flipped over to face substrate 302 towards the sun. When the final configuration of PV cell 300 has the substrate facing the sun, substrate 302 may contains a transparent material. When PV cell 300 is fabricated such that the substrate is opposite the sun, then other materials may be utilized as discussed above.

PV cell 300 contains p-i-n junction 310 formed on TCO layer 304 disposed on substrate 302. P-i-n junction 310 contains p-type α-Si film 312, n-type α-Si film 316, and an intrinsic type (i-type) α-Si layer 314 disposed therebetween as a photoelectric conversion layer. An optional dielectric layer (not shown) may be disposed between substrate 302 and TCO layer 304. In one embodiment, the optional dielectric layer may be a silicon layer including amorphous or polysilicon, SiON, SiN, SiC, SiOC, silicon oxide (SiO₂) layer, doped silicon layer, or any suitable silicon containing layer. In another embodiment, the optional dielectric layer may be a titanium based layer, such as containing titanium oxide, which provides a barrier to impurities that may be contained within substrate 302.

TCO layer 304 contains or is fabricated from a metal oxide such as tin oxide (e.g., SnO₂), indium tin oxide (ITO), zinc oxide (e.g., ZnO), cadmium stannate (e.g., Cd₂SnO₄), aluminum oxide or alumina (e.g., Al₂O₃), doped materials thereof, derivatives thereof, alloys thereof, or combinations thereof. TCO layer 304 contains at least one TCO material that has additional dopants or elements, such as aluminum, gallium, boron, fluorine, or mixtures thereof. In some examples, TCO layer 304 contains zinc oxide and a dopant with a dopant concentration of about 5 at % (atomic percent) or less, such as about 2.5 at % or less. In some examples, TCO layer 304 contains a zinc oxide doped with aluminum oxide or alumina at the desired dopant concentration. In one example, TCO layer 304 contains zinc oxide doped with aluminum oxide at a dopant concentration of about 2.5 at %. In another example, TCO layer 304 contains tin oxide doped with fluorine.

TCO layer 304 is deposited or otherwise formed by a physical vapor deposition (PVD) process, an electroless chemical deposition/plating process, a chemical vapor deposition (CVD) process, a plasma enhanced chemical vapor deposition (PE-CVD) process, or another deposition process. In many examples, TCO layer 304 is fabricated by a sputter deposition process, wherein the TCO material is either sputtered from a metal oxide target or sputtered from a metallic target within an oxidizing environment, such as a processing chamber containing atomic oxygen, oxygen gas, ozone, nitrous oxide, derivatives thereof, or another oxidizing agent. In some examples, substrate 302 having TCO layer 304 disposed thereon may be provided by a supplier (e.g., glass manufacturer). Several PVD processes which may be used to fabricate TCO materials for TCO layer 304 are further described in commonly assigned U.S. application Ser. Nos. 12/748,780 and 12/748,790, both filed Mar. 29, 2010, both entitled Method for Forming Transparent Conductive Oxide, and published as U.S. Pub. Nos. 2010-0311228 and 2010-0311204, which are incorporated by reference in their entirety to the extent not inconsistent with embodiments of the present disclosure.

The p-type α-Si film 312 contains a silicon-based material such as amorphous silicon (α-Si) which is doped by a Group III element. The silicon-based material, layer, or film doped with the Group III element is referred to as a p-doped or a p-type silicon material, layer, or film. In one example, p-type α-Si film 312 may contain a boron doped, amorphous silicon material. Alternatively, p-type α-Si film 312 may be doped with other elements selected to meet device requirements of PV cell 300. The p-type α-Si film 312 may be deposited by the PE-CVD processes described herein. The p-type α-Si film 312 generally has a total thickness within a range from about 10 Å and about 500 Å, more narrowly within a range from about 20 Å to about 300 Å, and more narrowly within a range from about 30 Å to about 200 Å.

The α-Si intrinsic film 314 is a non-doped type silicon based film. The α-Si intrinsic film 314 is deposited under process conditions controlled to provide film properties having improved photoelectric conversion efficiency. The α-Si intrinsic film 314 contains or is fabricated from an intrinsic (i-type) material, such as amorphous silicon or hydrogenated amorphous silicon (α-Si:H). The α-Si intrinsic film 314 generally has a total thickness within a range from about 10 Å and about 500 Å, more narrowly within a range from about 20 Å to about 300 Å, and more narrowly within a range from about 30 Å to about 200 Å.

The n-type α-Si film 316 contains a silicon-based material such as amorphous silicon which is doped by a Group V element. The silicon-based material, layer, or film doped with the Group V element is referred to as an n-doped or an n-type silicon material, layer, or film. In one example, n-type α-Si film 316 contains a phosphorus doped, amorphous silicon material. Alternatively, n-type α-Si film 316 is doped with other elements selected to meet device requirements of PV cell 300. The n-type α-Si film 316 is deposited by the PE-CVD processes described herein. The n-type α-Si film 316 generally has a thickness within a range from about 10 Å and about 500 Å, more narrowly within a range from about 20 Å to about 300 Å, and more narrowly within a range from about 30 Å to about 200 Å.

Subsequent the formation of p-i-n junction 310 on TCO layer 304, a back reflector 320 is generally fabricated on or over p-i-n junction 310. In one embodiment, back reflector 320 is fabricated forming a TCO layer 322 on the upper surface of p-i-n junction 310, such as n-type α-Si film 316, and thereafter, forming a metallic reflective layer 324 on TCO layer 322. Metallic reflective layer 324 generally contains or be fabricated from at least one metal, such as titanium, chromium, aluminum, nickel, silver, gold, copper, platinum, palladium, ruthenium, alloys thereof, or combinations thereof.

In some examples, TCO layer 322 contains the same material as TCO layer 304, and in other examples, TCO layer 322 contains a different material as TCO layer 304. TCO layer 322 contains or is fabricated from a metal oxide such as tin oxide, indium tin oxide, zinc oxide, cadmium stannate, aluminum oxide or alumina, doped materials thereof, derivatives thereof, alloys thereof, or combinations thereof. The materials contained within TCO layer 322 may include additional dopants or elements, such as aluminum, gallium, boron, fluorine, or mixtures thereof. In some examples, TCO layer 322 contains zinc oxide and a dopant with a dopant concentration of about 5 at % (atomic percent) or less, such as about 2.5 at % or less. In some examples, TCO layer 322 contains or is fabricated from a zinc oxide doped with aluminum oxide or alumina at the desired dopant concentration. In one example, TCO layer 322 is doped and contains a zinc oxide material having aluminum at a concentration of about 2.5 at %. In another example, TCO layer 322 is doped and contains a tin oxide material having a dopant of fluorine. TCO layer 322 may be formed by the same technique or a different technique as TCO layer 304 described above. Generally, TCO layer 322 is formed by a sputter deposition process, wherein the TCO material is either sputtered from a metal oxide target or sputtered from a metallic target within an oxidizing environment, such as a processing chamber containing oxygen, ozone, or other oxidizing agent.

In other examples, a method for forming an α-Si-based PV device includes exposing a TCO layer disposed on a substrate to hydrogen plasma within a processing chamber during a pretreatment process and forming a p-type α-Si film over the TCO layer within the processing chamber. Hydrogen plasma is generally formed by ionizing a stream of hydrogen gas. The method further includes forming an α-Si intrinsic film over the p-type α-Si film within the processing chamber during a PE-CVD process and forming an n-type α-Si film over the α-Si intrinsic film by exposing the substrate to hydrogen plasma, the silicon precursor gas, and a phosphorus precursor gas within the processing chamber.

In one example, the method to form the p-type α-Si film includes three steps. The first step of the method is performed by depositing a first p-type silicon layer on the TCO layer by exposing the substrate to hydrogen plasma, a silicon precursor gas, and a boron precursor gas. The second step of the method is performed by stopping the exposure of the silicon precursor gas and the boron precursor gas to the substrate while exposing the first p-type silicon layer to hydrogen plasma. The third step of the method is performed by depositing a second p-type silicon layer on the first p-type silicon layer by exposing the substrate to hydrogen plasma, the silicon precursor gas, and the boron precursor gas.

In another example, the method to form the α-Si intrinsic film over the p-type α-Si film within the processing chamber during a PE-CVD process is performed by depositing an α-Si intrinsic layer during a deposition step, treating the α-Si intrinsic layer to form a treated α-Si intrinsic layer during a plasma treatment step, and sequentially repeating the deposition step and the plasma treatment step while forming the α-Si intrinsic film containing a plurality of treated α-Si intrinsic layers.

In one embodiment, the deposition step of the PE-CVD process is performed by flowing a silicon precursor gas and hydrogen gas to the substrate, generating a first plasma by ionizing the silicon precursor gas and the hydrogen gas, and depositing the α-Si intrinsic layer. The plasma treatment step of the PE-CVD process is performed by generating a second plasma by stopping the flow of the silicon precursor gas to the substrate, maintaining the flow of the hydrogen gas to the substrate, and maintaining the ionization of the hydrogen gas, and exposing the α-Si intrinsic layer to the second plasma while forming the treated α-Si intrinsic layer.

In another embodiment, the PE-CVD process also includes a transition step, subsequent to the deposition step and prior to the plasma treatment step. The deposition step of the PE-CVD process is performed by flowing a silicon precursor gas and hydrogen gas to the substrate, generating a first plasma by ionizing the silicon precursor gas and the hydrogen gas, and depositing the α-Si intrinsic layer. Subsequently, the transition step of the PE-CVD process is performed by extinguishing the first plasma by stopping the ionization of the silicon precursor gas and the hydrogen gas, stopping the flow of the silicon precursor gas to the substrate, and maintaining the flow of the hydrogen gas to the substrate. Thereafter, the plasma treatment step is performed by maintaining the flow of the hydrogen gas to the substrate, generating a second plasma by ionizing the hydrogen gas, and exposing the α-Si intrinsic layer to the second plasma while forming the treated α-Si intrinsic layer.

While the foregoing is directed to embodiments of the invention, other and further embodiments of the invention may be devised without departing from the basic scope thereof, and the scope thereof is determined by the claims that follow.

1. A method for forming an amorphous silicon-based photovoltaic device, comprising:
exposing a transparent conductive oxide layer disposed on a substrate to a hydrogen plasma in a processing chamber during a pretreatment process;
forming a p-type amorphous silicon film over the transparent conductive oxide layer;
forming an amorphous silicon intrinsic film over the p-type amorphous silicon film during a plasma-enhanced chemical vapor deposition process, comprising:
depositing an amorphous silicon intrinsic layer during a deposition step; and
treating the amorphous silicon intrinsic layer to form a treated amorphous silicon intrinsic layer during a plasma treatment step; and
forming an n-type amorphous silicon film over the amorphous silicon intrinsic film.

2. The method of claim 1, wherein the plasma-enhanced chemical vapor deposition process is conducted in the processing chamber and further comprises:
flowing a silicon precursor gas and hydrogen gas to the substrate, generating a first plasma by ionizing the silicon precursor gas and the hydrogen gas, and depositing the amorphous silicon intrinsic layer during the deposition step;
extinguishing the first plasma by stopping the ionization of the silicon precursor gas and the hydrogen gas, stopping the flow of the silicon precursor gas to the substrate, and maintaining the flow of the hydrogen gas to the substrate during a transition step; and
maintaining the flow of the hydrogen gas to the substrate, generating a second plasma by ionizing the hydrogen gas, and exposing the amorphous silicon intrinsic layer to the second plasma while forming the treated amorphous silicon intrinsic layer during the plasma treatment step.

3. The method of claim 2, wherein the transition step lasts for a time period within a range from about 2 seconds to about 60 seconds.

4. The method of claim 2, wherein the deposition step, the transition step, and the plasma treatment step are sequentially repeated to form the amorphous silicon intrinsic film comprising a plurality of the treated amorphous silicon intrinsic layers.

5. The method of claim 4, wherein the deposition step, the transition step, and the plasma treatment step are sequentially repeated up to about 12 times.

6. The method of claim 1, wherein the plasma-enhanced chemical vapor deposition process is conducted in the processing chamber and further comprises:
the deposition step comprising:
flowing a silicon precursor gas and hydrogen gas to the substrate;
generating a first plasma by ionizing the silicon precursor gas and the hydrogen gas; and
depositing the amorphous silicon intrinsic layer; and
the plasma treatment step comprising:
generating a second plasma by stopping the flow of the silicon precursor gas to the substrate, maintaining the flow of the hydrogen gas to the substrate, and maintaining the ionization of the hydrogen gas; and
exposing the amorphous silicon intrinsic layer to the second plasma while forming the treated amorphous silicon intrinsic layer.

7. The method of claim 6, wherein the deposition step and the plasma treatment step each independently lasts for a time period within a range from about 2 seconds to about 60 seconds.

8. The method of claim 6, wherein the deposition step and the plasma treatment step are sequentially repeated to form the amorphous silicon intrinsic film comprising a plurality of the treated amorphous silicon intrinsic layers.

9. The method of claim 8, wherein the deposition step and the plasma treatment step are sequentially repeated up to about 12 times.

10. The method of claim 1, wherein the amorphous silicon intrinsic film comprises at least 2 and up to about 12 of the treated amorphous silicon intrinsic layers, and the amorphous silicon intrinsic film has a thickness within a range from about 500 Å to about 2,000 Å.

11. The method of claim 1, further comprising heating the substrate in the processing chamber to a temperature within a range from about 30° C. to about 300° C. during a preheat step prior to the pretreatment process.

12. The method of claim 1, wherein forming the p-type amorphous silicon film further comprises:
depositing a first p-type silicon layer on the transparent conductive oxide layer;
exposing the first p-type silicon layer to hydrogen plasma; and
depositing a second p-type silicon layer on the first p-type silicon layer.

13. A method for forming an amorphous silicon-based photovoltaic device, comprising:
exposing a transparent conductive oxide layer disposed on a substrate to a hydrogen plasma during a pretreatment process;
forming a p-type amorphous silicon film over the transparent conductive oxide layer;
forming an amorphous silicon intrinsic film over the p-type amorphous silicon film during a plasma-enhanced chemical vapor deposition process, comprising:
depositing an amorphous silicon intrinsic layer during a deposition step within a processing chamber;
treating the amorphous silicon intrinsic layer to form a treated amorphous silicon intrinsic layer during a plasma treatment step within the processing chamber; and
sequentially repeating the deposition step and the plasma treatment step while forming the amorphous silicon intrinsic film comprising a plurality of the treated amorphous silicon intrinsic layers; and
forming an n-type amorphous silicon film over the amorphous silicon intrinsic film.

14. The method of claim 13, wherein the plasma-enhanced chemical vapor deposition process further comprises:
the deposition step comprising:
flowing a silicon precursor gas and hydrogen gas to the substrate;
generating a first plasma by ionizing the silicon precursor gas and the hydrogen gas; and
depositing the amorphous silicon intrinsic layer; and
the plasma treatment step comprising:
generating a second plasma by stopping the flow of the silicon precursor gas to the substrate, maintaining the flow of the hydrogen gas to the substrate, and maintaining the ionization of the hydrogen gas; and
exposing the amorphous silicon intrinsic layer to the second plasma while forming the treated amorphous silicon intrinsic layer.

15. The method of claim 13, wherein the plasma-enhanced chemical vapor deposition process further comprises:
flowing a silicon precursor gas and hydrogen gas to the substrate, generating a first plasma by ionizing the silicon precursor gas and the hydrogen gas, and depositing the amorphous silicon intrinsic layer during the deposition step;
extinguishing the first plasma by stopping the ionization of the silicon precursor gas and the hydrogen gas, stopping the flow of the silicon precursor gas to the substrate, and maintaining the flow of the hydrogen gas to the substrate during a transition step; and
maintaining the flow of the hydrogen gas to the substrate, generating a second plasma by ionizing the hydrogen gas, and exposing the amorphous silicon intrinsic layer to the second plasma while forming the treated amorphous silicon intrinsic layer during the plasma treatment step.

16. The method of claim 13, wherein the amorphous silicon intrinsic film comprises at least 2 and up to about 12 of the treated amorphous silicon intrinsic layers, and the amorphous silicon intrinsic film has a thickness within a range from about 500 Å to about 2,000 Å.

17. The method of claim 13, wherein forming the p-type amorphous silicon film further comprises:
depositing a first p-type silicon layer on the transparent conductive oxide layer;
exposing the first p-type silicon layer to hydrogen plasma; and
depositing a second p-type silicon layer on the first p-type silicon layer.

18. A method for forming an amorphous silicon-based photovoltaic device, comprising:
exposing a transparent conductive oxide layer disposed on a substrate to a hydrogen plasma within a processing chamber during a pretreatment process, wherein the hydrogen plasma is formed by ionizing a stream of hydrogen gas;
forming a p-type amorphous silicon film over the transparent conductive oxide layer within the processing chamber, comprising:
depositing a first p-type silicon layer on the transparent conductive oxide layer by exposing the substrate to the hydrogen plasma, a silicon precursor gas, and a boron precursor gas during a first step;
stopping the exposure of the silicon precursor gas and the boron precursor gas to the substrate while exposing the first p-type silicon layer to the hydrogen plasma during a second step; and
depositing a second p-type silicon layer on the first p-type silicon layer by exposing the substrate to the hydrogen plasma, the silicon precursor gas, and the boron precursor gas during a third step;
forming an amorphous silicon intrinsic film over the p-type amorphous silicon film within the processing chamber during a plasma-enhanced chemical vapor deposition process, comprising:
depositing an amorphous silicon intrinsic layer during a deposition step;
treating the amorphous silicon intrinsic layer to form a treated amorphous silicon intrinsic layer during a plasma treatment step; and
sequentially repeating the deposition step and the plasma treatment step while forming the amorphous silicon intrinsic film comprising a plurality of the treated amorphous silicon intrinsic layers; and
forming an n-type amorphous silicon film over the amorphous silicon intrinsic film by exposing the substrate to the hydrogen plasma, the silicon precursor gas, and a phosphorus precursor gas within the processing chamber.

19. The method of claim 18, wherein the plasma-enhanced chemical vapor deposition process further comprises:
the deposition step comprising:
flowing a silicon precursor gas and hydrogen gas to the substrate;
generating a first plasma by ionizing the silicon precursor gas and the hydrogen gas; and
depositing the amorphous silicon intrinsic layer; and
the plasma treatment step comprising:
generating a second plasma by stopping the flow of the silicon precursor gas to the substrate, maintaining the flow of the hydrogen gas to the substrate, and maintaining the ionization of the hydrogen gas; and
exposing the amorphous silicon intrinsic layer to the second plasma while forming the treated amorphous silicon intrinsic layer.

20. The method of claim 18, wherein the plasma-enhanced chemical vapor deposition process further comprises:
flowing a silicon precursor gas and hydrogen gas to the substrate, generating a first plasma by ionizing the silicon precursor gas and the hydrogen gas, and depositing the amorphous silicon intrinsic layer during the deposition step;
extinguishing the first plasma by stopping the ionization of the silicon precursor gas and the hydrogen gas, stopping the flow of the silicon precursor gas to the substrate, and maintaining the flow of the hydrogen gas to the substrate during a transition step; and
maintaining the flow of the hydrogen gas to the substrate, generating a second plasma by ionizing the hydrogen gas, and exposing the amorphous silicon intrinsic layer to the second plasma while forming the treated amorphous silicon intrinsic layer during the plasma treatment step.
